(19) United States
(12) Patent Application Publication
(10) Pub. No.: US 2025/0022757 A1
(43) Pub. Date: Jan. 16, 2025

(54) SEMICONDUCTOR MANUFACTURING APPARATUS, INFORMATION PROCESSING APPARATUS, AND RADIO-FREQUENCY VIBRATION DATA ANALYSIS METHOD

(71) Applicant: Tokyo Electron Limited, Tokyo (JP)

(72) Inventors: Tadashi ENOMOTO, Iwate (JP); Takeshi KONGOJI, Yamanashi (JP); GEDARA WATTAGE SUDATH LAKSHMAN WIJEWARDANA, Yamanashi (JP)

(21) Appl. No.: 18/768,254

(22) Filed: Jul. 10, 2024

(30) Foreign Application Priority Data
Jul. 14, 2023 (JP) 2023-115730

(51) Int. Cl. H01L 21/66

(52) U.S. Cl. CPC H01L 22/12; H01L 22/34

(57) ABSTRACT

A semiconductor manufacturing apparatus includes a first controller that collects radio-frequency vibration data; and a second controller that analyzes the radio-frequency vibration data. The first controller includes a collection unit that collects the radio-frequency vibration data from a sensor, a fast Fourier transform (FFT) unit that performs a FFT processing on the radio-frequency vibration data according to a resolution setting, a FFT data transmission unit that transmits FFT data generated by the FFT processing, to the second controller, and a radio-frequency vibration data transmission unit that transmits the radio-frequency vibration data in a time period in which the FFT data exceeds a threshold value for an abnormality prediction, to the second controller The higher-level controller includes an analysis unit that analyzes the FFT data and the radio-frequency vibration data in the time period.

### CROSS-REFERENCE TO RELATED APPLICATIONS

This application is based on and claims priority from Japanese Patent Application No. 2023-115730 filed on Jul. 14, 2023, with the Japan Patent Office, the disclosure of which is incorporated herein in its entirety by reference.

### TECHNICAL FIELD

The present disclosure relates to a semiconductor manufacturing apparatus, an information processing apparatus, and a radio-frequency vibration data analysis method.

### BACKGROUND

Abnormality detection systems utilizing Acoustic Emission (AE) have been known in the art. As an analysis method of an AE signal detected by a sensor, there is a method of performing high-speed sampling of an output signal of a sensor and handling high-volume data generated by the high-speed sampling (see, e.g., Japanese Patent No. 5363213).

### SUMMARY

An aspect of the present disclosure provides a semiconductor manufacturing apparatus including a first controller and a second controller. The first controller collects radio-frequency vibration data; and the second controller analyzes the radio-frequency vibration data. The first controller includes a collection unit that collects the radio-frequency vibration data from a sensor, a fast Fourier transform (FFT) unit that performs a FFT processing on the radio-frequency vibration data according to a resolution setting, a FFT data transmission unit that transmits FFT data generated by the FFT processing, to the second controller, and a radio-frequency vibration data transmission unit that transmits the radio-frequency vibration data in a time period in which the FFT data exceeds a threshold value for an abnormality prediction, to the second controller. The second controller includes an analysis unit that analyzes the FFT data and the radio-frequency vibration data in the time period in which the FFT data exceeds the threshold value for the abnormality prediction, which are received from the FFT data transmission unit and the radio-frequency vibration data transmission unit, respectively.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 illustrates a schematic configuration of a semiconductor manufacturing apparatus according to an embodiment of the present disclosure.

FIG. 2 illustrates a hardware configuration of a computer.

FIG. 3 illustrates a functional configuration of a lower-level controller.

FIG. 4 illustrates a functional configuration of a higher-level controller.

FIG. 5 is a flowchart illustrating a processing of the lower-level controller according to the embodiment.

FIGS. 6A and 6B illustrate a setting of a threshold value for an abnormality prediction.

FIGS. 7A, 7B and 7C illustrate a setting of a threshold value for an abnormality prediction.

FIGS. 8A and 8B illustrate a setting of a threshold value for an abnormality prediction.

FIGS. 9A and 9B illustrate a setting of a threshold value for an abnormality prediction.

FIG. 10 illustrates a setting of a threshold value for an abnormality prediction.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure, which are illustrative but not limited, will be described with reference to the accompanying drawings. In the accompanying drawings, the same or corresponding members or parts are designated by the same or corresponding reference numerals, and duplicate descriptions thereof will be omitted as appropriate.

### First Embodiment

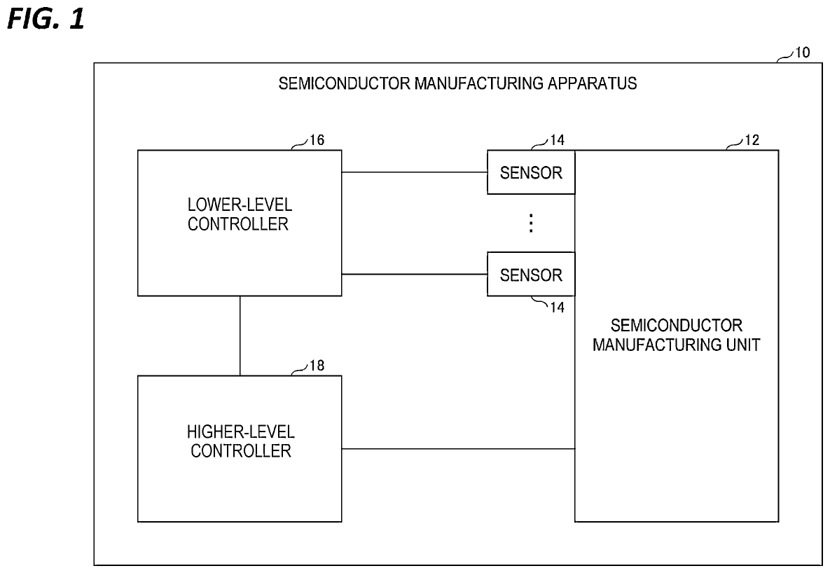

FIG. 1 illustrates a schematic configuration of a semiconductor manufacturing apparatus according to an embodiment of the present disclosure. A semiconductor manufacturing apparatus 10 of FIG. 1 includes a semiconductor manufacturing unit 12, one or more sensors 14 installed on the semiconductor manufacturing unit 12, a lower-level controller 16, and a higher-level controller 18. The lower-level controller 16 may be installed outside a housing of the semiconductor manufacturing apparatus 10. The higher-level controller 18 may be installed outside the housing of the semiconductor manufacturing apparatus 10. For example, the lower-level controller 16 and the higher-level controller 18 may be implemented using a computer, which is connected to enable data communication through a network, or a cloud service, which is available through the network.

The semiconductor manufacturing unit 12 includes, for example, a heat treatment furnace and performs various heat treatments such as oxidation, diffusion, and low-pressure chemical vaper deposition (CVD) on a wafer W, which is an example of a processing target substrate. The sensor 14 detects radio-frequency vibration data from the semiconductor manufacturing unit 12. The sensor 14 is, for example, an Acoustic Emission (AE) sensor, which is a type of vibration sensor.

The lower-level controller 16 is, for example, a controller for controlling the semiconductor manufacturing apparatus 10. The lower-level controller 16 may be a device used to accumulate the radio-frequency vibration data detected by the sensor 14. The lower-level controller 16 may be, for example, a data collection device such as a data logger. The lower-level controller 16 collects the radio-frequency vibration data from the sensor 14 and performs a fast Fourier transform (hereinafter, referred to as FFT) processing on the radio-frequency vibration data according to a resolution setting to be described later. The lower-level controller 16 transmits FFT data which is generated by the FFT processing, to the higher-level controller 18.

The lower-level controller 16 transmits, to the higher-level controller 18, radio-frequency vibration data in a time period in which the FFT data generated by the FFT processing exceeds a threshold value (trigger level) for an abnormality prediction, which will be described later. The lower-level controller 16 may transmit, to the higher-level controller 18, radio-frequency vibration data in a time period in which an instruction from the higher-level controller 18 is present. The lower-level controller 16 may manually receive a setting of a threshold value for the abnormality prediction, which will be described later, from an operator.

The higher-level controller 18 is a device that receives the FFT data and the radio-frequency vibration data from the lower-level controller 16 as described above and analyzes the data. The higher-level controller 18 may be, for example, an autonomous controller. The autonomous controller is a controller for autonomously controlling the semiconductor manufacturing apparatus 10, and performs, for example, optimization of apparatus control and prediction and detection of apparatus abnormalities. The higher-level controller 18 may set a resolution setting, which will be described later, in the lower-level controller 16.

The higher-level controller 18 may also set a threshold value for the abnormality prediction, which will be described later, in the lower-level controller 16. The higher-level controller 18 may detect and predict an abnormality in the semiconductor manufacturing apparatus 10 by analyzing the FFT data and the radio-frequency vibration data, which are received from the lower-level controller 16. The lower-level controller 16 and the higher-level controller 18 control an operation of the semiconductor manufacturing apparatus 10 to perform a semiconductor manufacturing processing under various processing conditions indicated in a recipe.

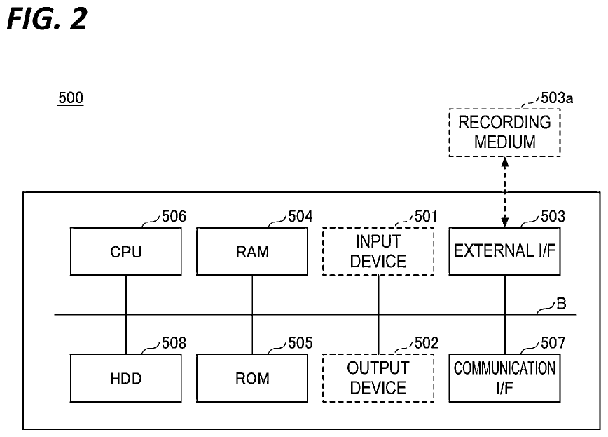

The lower-level controller 16 and the higher-level controller 18 are implemented by a computer with a hardware configuration illustrated in FIG. 2, for example. FIG. 2 illustrates a hardware configuration of a computer.

A computer 500 in FIG. 2 includes an input device 501, an output device 502, an external I/F (interface) 503, a random access memory (RAM) 504, a read only memory (ROM) 505, a central processing unit (CPU) 506, a communication I/F 507, and a hard disk drive (HDD) 508, all of which are connected to each other via a bus B. The input device 501 and the output device 502 may be connected to be used when necessary.

The input device 501 is a keyboard, a mouse, or a touch panel, and is used by an operator to input various operation signals. The output device 502 is a display and displays a result of processing by the computer 500. The communication I/F 507 is an interface that connects the computer 500 to a network. The HDD 508 is an example of a non-volatile storage device that stores programs and data.

The external I/F 503 is an interface to an external device. The computer 500 may perform reading and/or recording on a recording medium 503a, such as a secure digital (SD) memory card, via the external I/F 503. The ROM 505 is an example of a non-volatile semiconductor memory (storage device) in which programs or data are stored. The RAM 504 is an example of a volatile semiconductor memory (storage device) that temporarily holds programs or data.

The CPU 506 is a computing device that reads programs or data from the storage device such as the ROM 505 or the HDD 508 and executes a processing to implement control or functions of the entire computer 500.

The lower-level controller 16 or the higher-level controller 18 may implement various functions to be described below, as the computer 500 with the hardware configuration illustrated in FIG. 2 executes a processing according to a program.

### <Functional Configuration>

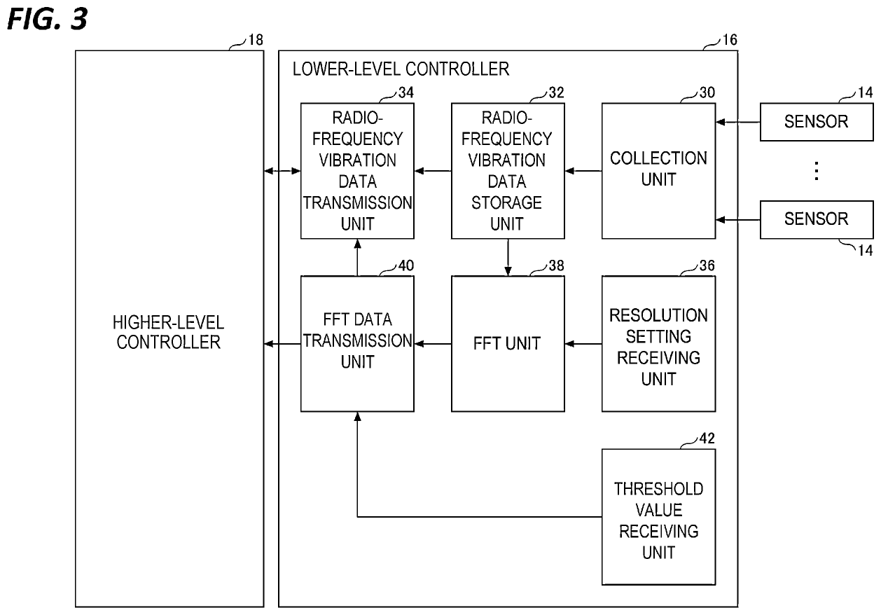

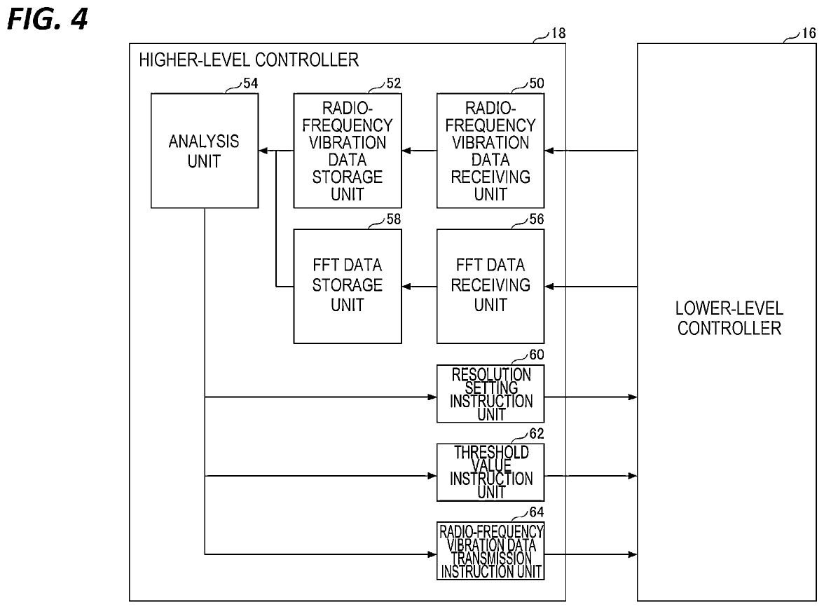

Examples of functional configurations of the lower-level controller 16 and the upper-level controller 18 will be described with reference to the attached drawings. FIG. 3 illustrates a functional configuration of a lower-level controller. FIG. 4 illustrates a functional configuration of a high-level controller.

The lower-level controller 16 illustrated in FIG. 3 includes a collection unit 30, a radio-frequency vibration data storage unit 32, a radio-frequency vibration data transmission unit 34, a resolution setting receiving unit 36, a FFT unit 38, a FFT data transmission unit 40, and a threshold value receiving unit 42.

The sensor 14 is installed at a position of the semiconductor manufacturing unit 12, where radio-frequency vibration data to be detected (hereinafter, referred to as raw data) may be detected. The collection unit 30 collects raw data detected by the sensor 14.

The radio-frequency vibration data storage unit 32 stores the raw data collected by the collection unit 30. The radio-frequency vibration data storage unit 32 has capacity sufficient to store the raw data collected by the collection unit 30, for example, raw data for about 500 hours.

The resolution setting receiving unit 36 receives a resolution setting from the higher-level controller 18. The resolution setting sets the number of waveform points in the FFT processing. In addition, the resolution setting receiving unit 36 may receive a resolution setting from an operator operating a monitor of the lower-level controller 16. The FFT unit 38 performs a FFT processing on the raw data according to the resolution setting received by the resolution setting receiving unit 36 and outputs FFT data.

The FFT data transmission unit 40 transmits the FFT data output by the FFT unit 38 to the higher-level controller 18. The FFT data transmission unit 40 also receives a setting of a threshold value for the abnormality prediction of the FFT data from the threshold value receiving unit 42. The threshold value receiving unit 42 may also receive the setting of the threshold value for the abnormality prediction from the operator operating the monitor of the lower-level controller 16.

The FFT data transmission unit 40 detects a moment when the FFT data exceeds the threshold value for the abnormality prediction as a trigger point, and notifies the radio-frequency vibration data transmission unit 34 of the time period in which the FFT data exceeds the threshold value for the abnormality prediction.

When the radio-frequency vibration data transmission unit 34 is notified, from the FFT data transmission unit 40, of the time period in which the FFT data exceeds the threshold value for the abnormality prediction, the radio-frequency vibration data transmission unit 34 reads raw data in the time period in which the FFT data exceeds the threshold value for the abnormality prediction from the radio-frequency vibration data storage unit 32, and transmits the raw data to the higher-level controller 18. Also, the radio-frequency vibration data transmission unit 34 may transmit raw data in an arbitrary time period in which an instruction from the high-level controller 18 is present, to the high-level controller 18.

The high-level controller 18 in FIG. 4 includes a radio-frequency vibration data receiving unit 50, a radio-frequency vibration data storage unit 52, an analysis unit 54, a FFT data receiving unit 56, a FFT data storage unit 58, a resolution setting instruction unit 60, a threshold value instruction unit 62, and a radio-frequency vibration data transmission instruction unit 64.

The radio-frequency vibration data receiving unit 50 receives the raw data from the radio-frequency vibration data transmission unit 34 of the lower-level controller 16. The raw data received by the radio-frequency vibration data receiving unit 50 is the raw data in the time period in which the FFT data exceeds the threshold value for the abnormality prediction or the raw data in an arbitrary time period in which an instruction from the high-level controller 18 is present. Thus, in the raw data received by the radio-frequency vibration data receiving unit 50, the amount of the raw data is much less than that of the raw data collected by the collection unit 30, so that an overhead of communication may be significantly reduced.

The radio-frequency vibration data storage unit 52 stores the raw data received by the radio-frequency vibration data receiving unit 50. The raw data received by the radio-frequency vibration data receiving unit 50 is the raw data in the time period in which the FFT data exceeds the threshold value for the abnormality prediction or the raw data in an arbitrary time period in an instruction from the high-level controller 18 is present. The amount of the raw data received by the radio-frequency vibration data receiving unit 50 is much less than that of the raw data collected by the collection unit 30, so that storage capacity of the radio-frequency vibration data storage unit 52 may be saved.

The FFT data receiving unit 56 receives the FFT data from the FFT data transmission unit 40 of the lower-level controller 16. The FFT data storage unit 58 stores the FFT data received by the FFT data receiving unit 56. The analysis unit 54 may analyze the raw data stored in the radio-frequency vibration data storage unit 52 and the FFT data stored in the FFT data storage unit 58, thereby performing optimization of apparatus control and prediction and detection of apparatus abnormalities of the semiconductor manufacturing apparatus 10.

For example, the analysis unit 54 determines the resolution setting according to a known analysis algorithm. The resolution setting instruction unit 60 instructs the lower-level controller 16 on the determined resolution setting. The analysis unit 54 also determines the threshold value for the abnormality prediction according to a known analysis algorithm. The threshold value instruction unit 62 instructs the lower-level controller 16 on the determined threshold value for the abnormality prediction. The radio-frequency vibration data transmission instruction unit 64 instructs the lower-level controller 16 on an arbitrary time period of the raw data, which is received from the lower-level controller 16.

### <Processing>

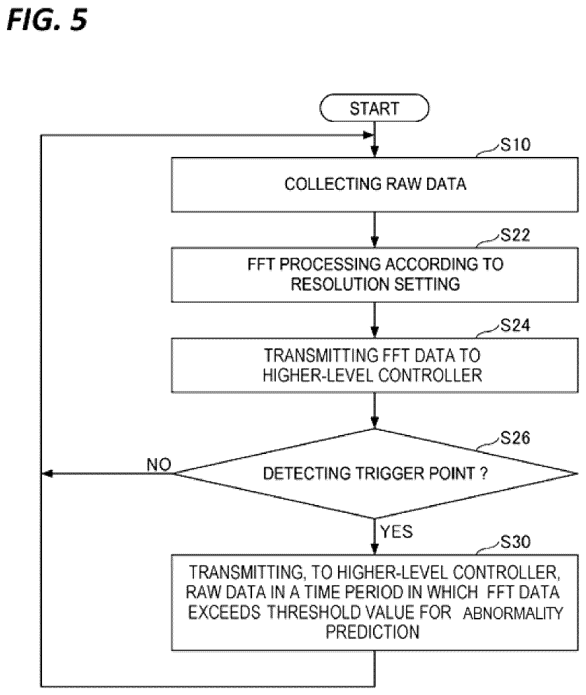

Hereinafter, a radio-frequency vibration data analysis method of the semiconductor manufacturing apparatus 10 according to the embodiment of the present disclosure will be described. The lower-level controller 16 of the semiconductor manufacturing apparatus 10 performs a processing according to a procedure illustrated in FIG. 5, for example. FIG. 5 is a flowchart illustrating a processing of the lower-level controller according to the embodiment.

In step S10, the collection unit 30 of the lower-level controller 16 collects the raw data detected by the sensor 14. In step S22, the FFT unit 38 performs the FFT processing on the raw data according to the resolution setting received by the resolution setting receiving unit 36, and outputs FFT data.

The resolution setting sets the number of waveform points in the FFT processing. For example, a 1024 resolution, a 2048 resolution, or a 4096 resolution is set by the resolution setting. For example, when the 4096 resolution is set, the number of waveform points is approximately ½. For example, when the 2048 resolution is set, the number of waveform points is approximately ¼. For example, when the 1024 resolution is set, the number of waveform points is approximately ⅛.

In step S24, the FFT data transmission unit 40 transmits the FFT data output by the FFT unit 38 to the higher-level controller 18. In this manner, the semiconductor manufacturing apparatus 10 according to the embodiment transmits the FFT data which is in accordance with the resolution setting required by the higher-level controller 18, from the lower-level controller 16 to the higher-level controller 18 all the time.

For example, when the raw data detected by the sensor 14 is radio-frequency data, and when all or substantially all of the raw data detected by the sensor 14 is transmitted to the higher-level controller 18, there is a limitation in that a great amount of raw data in a normal state is actually transmitted. In addition, since the state of abnormalities in radio-frequency vibrations often changes during an extended time period of operation, for example, the raw data for about 10 minutes per day, among the raw data detected by the sensor 14, may be transmitted to the higher-level controller 18. When the raw data for about 10 minutes per day among the raw data detected by the sensor 14, is transmitted to the higher-level controller 18, it is raw data in a fixed time period, so that it may be difficult to perform a time-synchronized analysis with an arbitrary operation of the semiconductor manufacturing apparatus 10.

In the semiconductor manufacturing apparatus 10 according to the embodiment, the higher-level controller 18 receives the FFT data according to the resolution setting required by the higher-level controller 18 all the time, so that it is possible to implement analysis associated with explanatory variables of the time-synchronized arbitrary operation of the semiconductor manufacturing apparatus 10.

In step S26, the FFT data transmission unit 40 determines whether or not the trigger point is detected, which is the moment when the threshold value for an abnormality prediction, the setting of which has been received by the threshold value receiving unit 42 is exceeded. When the trigger point is not detected, the semiconductor manufacturing apparatus 10 returns to step S10 and continues the processing.

When the trigger point is detected, the FFT data transmission unit 40 proceeds to step S30. In step S30, the FFT data transmission unit 40 notifies the radio-frequency vibration data transmission unit 34 of the detection of the trigger point. The FFT data transmission unit 40 may notify the radio-frequency vibration data transmission unit 34 of the time period in which the FFT data exceeds the threshold value for the abnormality prediction.

When notified of the detection of the trigger point from the FFT data transmission unit 40, the radio-frequency vibration data transmission unit 34 reads raw data in the time period in which the FFT data exceeds the threshold value for the abnormality prediction from the radio-frequency vibration data storage unit 32 and transmits the raw data to the higher-level controller 18. The time period in which the FFT data exceeds the threshold value for the abnormality prediction may be, for example, 5 to 60 minutes before and after the trigger point. The threshold value for the abnormality prediction may be set using an automatic trigger detection function by data analysis of the higher-level controller 18.

The radio-frequency vibration data transmission unit 34 may select raw data in the time period in which the FFT data exceeds the threshold value for the abnormality prediction and transmit the raw data to the higher-level controller 18, thereby significantly reducing the overhead of communication between the lower-level controller 16 and the higher-level controller 18, compared to transmitting all of the raw data.

In addition, by selecting the raw data in the time period in which the FFT data exceeds the threshold value for the abnormality prediction and transmitting the raw data to the higher-level controller 18, the higher-level controller 18 may perform a more detailed analysis thereon, compared to the FFT data. After step S30, the semiconductor manufacturing apparatus 10 according to the embodiment returns to step S10 and continues the processing.

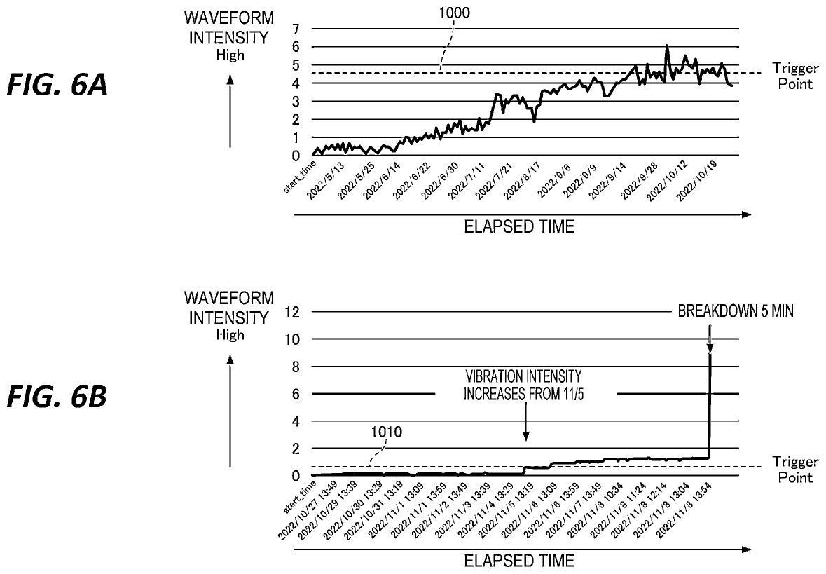

Hereinafter, the setting of the threshold value for the abnormality prediction will be described. FIGS. 6A and 6B illustrate a setting of a threshold value for an abnormality prediction. FIGS. 6A and 6B illustrate changes in waveform intensity over time. The waveform intensity in FIGS. 6A and 6B is the sum of intensities for each of frequencies.

By setting a threshold value 1000 for an abnormality prediction in FIG. 6A, a moment when the waveform intensity exceeds the threshold value 1000 may be detected as a trigger point. Also, by setting a threshold value 1010 for an abnormality prediction in FIG. 6B, a moment when a vibration intensity increases and the waveform intensity exceeds the threshold value 1010 may be detected as a trigger point.

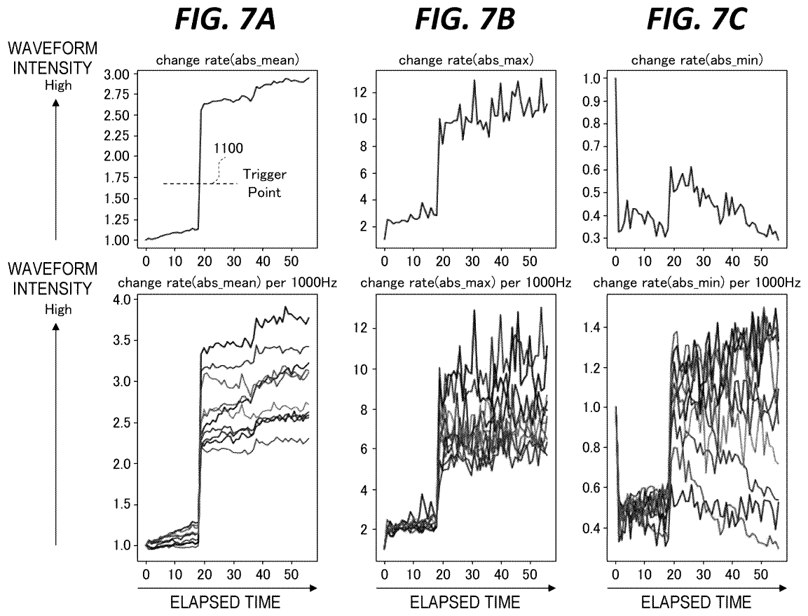

FIGS. 7A, 7B and 7C illustrate a setting of a threshold value for an abnormality prediction. In FIG. 7A, by setting a threshold value 1100 for an abnormality prediction regarding an average of waveform intensities, a moment when the average of the waveform intensities exceeds the threshold value 1100 may be detected as a trigger point. In FIG. 7B, by setting a threshold value for an abnormality prediction regarding a maximum value of the waveform intensity, a moment when the maximum value of the waveform intensity exceeds the threshold value may be detected as a trigger point. In addition, in FIG. 7C, by setting a threshold value for an abnormality prediction regarding a minimum value of the waveform intensity, a moment when the minimum value of the waveform intensity exceeds the threshold value may be detected as a trigger point.

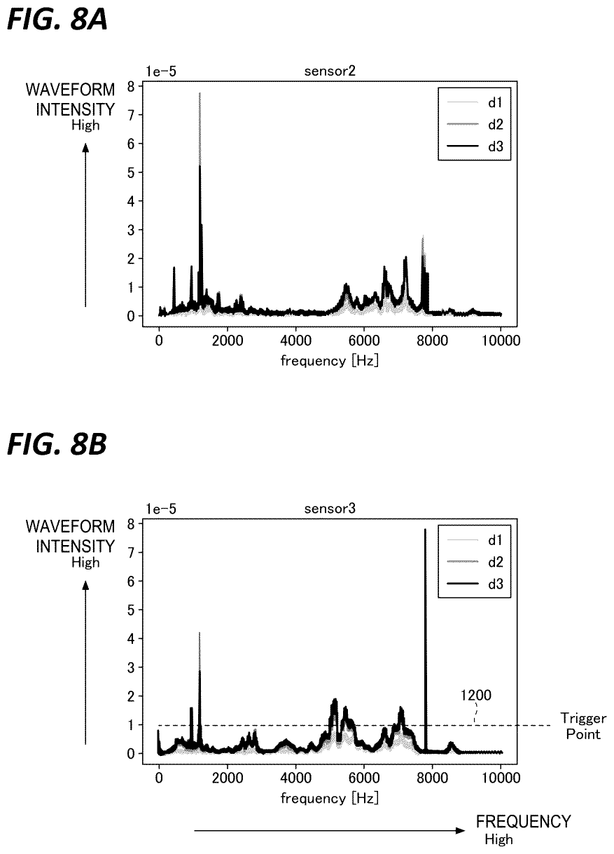

FIGS. 8A and 8B illustrate a setting of a threshold value for an abnormality prediction. FIGS. 8A and 8B illustrate changes in waveform intensity over time for each frequency. For example, the symbol “d1” in FIGS. 8A and 8B illustrates a waveform intensity for each frequency in an initial state of the semiconductor manufacturing apparatus 10.

The symbols “d2” and “d3” in FIGS. 8A and 8B illustrate waveform intensities for each frequency in a changing state over time of the semiconductor manufacturing apparatus 10 after a predetermined period of time has passed since the initial state. The period of time that has passed since the initial state of “d3” in FIGS. 8A and 8B is longer than “d2” in FIGS. 8A and 8B. In FIG. 8B, by setting a threshold value 1200 for an abnormality prediction regarding a waveform intensity for each frequency after a change over time of the semiconductor manufacturing apparatus 10 since the initial state thereof, a moment when the waveform intensity for each frequency exceeds the threshold value 1200 may be detected as a trigger point.

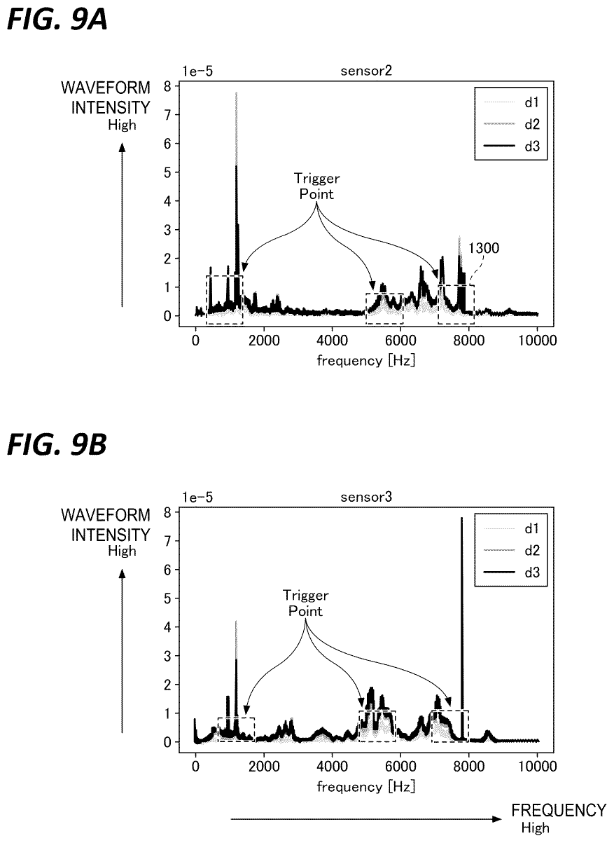

FIGS. 9A and 9B illustrate a setting of a threshold value for an abnormality prediction. FIGS. 9A and 9B illustrate changes in waveform intensity over time for each frequency. For example, the symbol “d1” in FIGS. 9A and 9B illustrates a waveform intensity for each frequency in the initial state of the semiconductor manufacturing apparatus 10.

The symbols “d2” and “d3” in FIGS. 9A and 9B illustrate waveform intensities for each frequency in a changing state over time of the semiconductor manufacturing apparatus 10 after a predetermined period of time has passed since the initial state. The period of time that has passed since the initial state of “d3” in FIGS. 9A and 9B is longer than “d2” in FIGS. 9A and 9B.

In FIGS. 9A and 9B, by setting a threshold value 1300 for an abnormality prediction in each arbitrary frequency range, a moment when a waveform intensity for each frequency exceeds the threshold value 1300 set in each arbitrary frequency range may be detected as a trigger point.

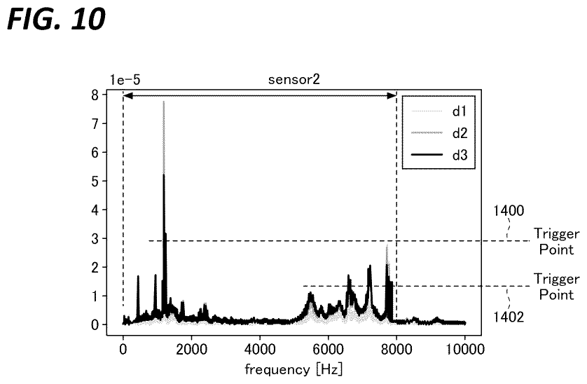

FIG. 10 illustrates a setting of a threshold value for an abnormality prediction. FIG. 10 illustrates an example of specifying a range of 0 to 8 kHz in a frequency band of 0 to 10 kHz, and averaging frequency bands before and after the frequency band, thereby outputting a waveform of 2048 points, which is about ¼ of 8000 Hz.

In FIG. 10, by setting at least one of a threshold value 1400 for an abnormality prediction, which is less than characteristic 1.5 kHz and a threshold value 1402 for an abnormality prediction, which is more than 5 kHz to 8 kHz, a moment when a waveform intensity for each frequency, which is less than 1.5 kHz exceeds the threshold value 1400 for the abnormality prediction or a waveform intensity for each of frequencies ranging from 5 kHz to 8 kHz exceeds the threshold value 1402 for the abnormality prediction may be detected as a trigger point.

When a range of 0 to 8192 Hz is specified and output is made at the 1024 resolution and 8 Hz intervals, the amount of data is ⅛. When a range of 0 to 8192 Hz is specified, and output is made at the 2048 resolution and 4 Hz intervals, the amount of data is ¼. When a range of 0 to 8192 Hz is specified, and output is made at the 4096 resolution and 2 Hz intervals, the amount of data is ½.

According to the embodiment, since the raw data in the time period in which the FFT data exceeds the threshold value for the abnormality prediction is transmitted to the higher-level controller 18, a processing load required to analyze the raw data may be reduced, thereby decreasing the time required to analyze the raw data.

In addition, according to the embodiment, since a resolution setting required for the high-level controller 18 may be specified from the high-level controller 18, PDCA (plan, do, check, and act) cycles for data collection, accumulation, and analysis are rotated by using an analysis algorithm, and the improvement of analysis accuracy may be automated.

According to the embodiment of the present disclosure, it is possible to reduce the time required to analyze the radio-frequency vibration data.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A semiconductor manufacturing apparatus comprising:
a first controller configured to collect radio-frequency vibration data; and
a second controller configured to analyze the radio-frequency vibration data collected at the first controller,
wherein the first controller includes:
a collection circuitry that collects the radio-frequency vibration data from a sensor,
a fast Fourier transform (FFT) circuitry that performs a FFT processing on the radio-frequency vibration data according to a resolution setting,
a FFT data transmission circuitry that transmits FFT data generated by the FFT processing, to the second controller, and
a radio-frequency vibration data transmission circuitry that transmits the radio-frequency vibration data in a time period in which the FFT data exceeds a threshold value for an abnormality prediction, to the second controller, and
wherein the second controller includes:
an analysis circuitry that analyzes the FFT data and the radio-frequency vibration data in the time period in which the FFT data exceeds the threshold value for the abnormality prediction, which are received from the FFT data transmission circuitry and the radio-frequency vibration data transmission circuitry, respectively.

2. The semiconductor manufacturing apparatus according to claim 1, wherein the resolution setting is performed according to an instruction from the second controller or an instruction from an operator operating the first controller.

3. The semiconductor manufacturing apparatus according to claim 1, wherein the resolution setting is performed such that the number of waveform points becomes 1024, 2048, or 4096.

4. The semiconductor manufacturing apparatus according to claim 1, wherein the threshold value for the abnormality prediction is set according to an instruction from the second controller, and
the radio-frequency vibration data transmission circuitry transmits, to the second controller, the radio-frequency vibration data in a set time period before and after the FFT data exceeds the threshold value for the abnormality prediction.

5. The semiconductor manufacturing apparatus according to claim 4, wherein the radio-frequency vibration data transmission circuitry transmits, to the second controller, the radio-frequency vibration data in a time period in which the instruction from the second controller is present.

6. The semiconductor manufacturing apparatus according to claim 1, wherein the radio-frequency vibration data is collected from an Acoustic Emission (AE) sensor.

7. An information processing apparatus comprising:
a collection circuitry configured to collect radio-frequency vibration data from a sensor of a semiconductor manufacturing apparatus;
a fast Fourier transform (FFT) circuitry configured to perform a FFT processing on the radio-frequency vibration data according to a resolution setting;
a FFT data transmission circuitry configured to transmit FFT data generated by the FFT processing, to a controller, and
a radio-frequency vibration data transmission circuitry configured to transmit the radio-frequency vibration data in a time period in which the FFT data exceeds a threshold value for an abnormality prediction, to the controller that analyzes the radio-frequency vibration data.

8. A method of analyzing radio-frequency vibration data of a semiconductor manufacturing apparatus including a first controller and a second controller, the method comprising:
collecting, by the first controller, the radio-frequency vibration data from a sensor of the semiconductor manufacturing apparatus,
performing, by the first controller, a fast Fourier transform (FFT) processing on the radio-frequency vibration data according to a resolution setting,
transmitting, by the first controller, FFT data generated by the FFT processing, to the second controller, and
transmitting, by the first controller, the radio-frequency vibration data in a time period in which the FFT data exceeds a threshold value for an abnormality prediction, to the second controller, and
analyzing, by the second controller, the FFT data and the radio-frequency vibration data in the time period in which the FFT data exceeds the threshold value for the abnormality prediction.

9. The semiconductor manufacturing apparatus according to claim 1, wherein the second controller is a higher-level controller than the first controller.

10. The method according to claim 8, wherein the second controller is a higher-level controller than the first controller.
